(19) United States
(12) Patent Application Publication
(10) Pub. No.: US 2010/0156562 A1
(43) Pub. Date: Jun. 24, 2010

(54) WIDEBAND VARIABLE FREQUENCY BAND PASS FILTER

(75) Inventor: Sang-Won KIM, Daejeon-City (KR)

Correspondence Address: LADAS & PARRY LLP, 224 SOUTH MICHIGAN AVENUE, SUITE 1600, CHICAGO, IL, 60604, US

(73) Assignee: Electronics and Telecommunications Research Institute, Daejeon-city (KR)

(21) Appl. No.: 12/643,064

(22) Filed: Dec. 21, 2009

(30) Foreign Application Priority Data
Dec. 22, 2008 (KR) 10-2008-0131177

(51) Int. Cl. H03H 7/00

(52) U.S. Cl. 333/174

(57) ABSTRACT

A wideband variable frequency band pass filter of an IEEE 802.22 wireless regional area network (WRAN) system operating in a very high frequency (VHF)/ultra high frequency (UHF) TV broadcast band.

### CROSS-REFERENCE TO RELATED PATENT APPLICATION

This application claims the benefit of Korean Patent Application No. 10-2008-0131177, filed on Dec. 22, 2008, in the Korean Intellectual Property Office, the disclosure of which is incorporated herein in its entirety by reference.

### BACKGROUND OF THE INVENTION

1. Field of the Invention

The present invention relates to a wideband variable frequency band pass filter, and more particularly to, a wideband variable frequency band pass filter capable of simultaneously changing a bandwidth and a central frequency, which are core radio frequency (RF) elements of an IEEE 802.22 wireless regional area network (WRAN) system operating in a very high frequency (VHF)/ultra high frequency (UHF) wideband.

2. Description of the Related Art

Radio propagation has been used in different kinds of fields, such as wireless Internet electronic commerce, transportation, disaster rescue, etc., and a demand for wideband multimedia has increased, which causes a lack of frequency.

In particular, owing to the excellent characteristics of radio propagation, a lack of frequency has been serious at a band lower than 3 GHz, which is most preferable to a wireless communication service.

However, a majority of previously allocated frequencies is not in use or has low efficiency and thus a method of utilizing previously allocated frequencies is needed.

In terms of utilizing given frequencies, a 2^{nd} generation mobile communication market of a band between 800 MHz and 1.8 GHz has been developed, and a 3^{rd} generation mobile communication service of a 2 GHz band has appeared. In addition, the demand for a future wideband mobile Internet access service is expected to continue while revitalizing a wireless local area network (WLAN) in the 2.4 GHz industrial, scientific, and medical (ISM) band and 5 GHz bands and commercializing a WiBro service in a 2.3 GHz band in the future.

Together with the revitalization of a wireless personal area network (WPAN) based on the home network market, a new spectrum utilization technology, such as ultra wideband (UWB), is expected to appear.

Such a rapidly developing wireless communication system requires an allocation of various bands according to an application environment, and continuously requires an extension of frequency bands according to a wideband wireless service.

Therefore, a policy issue is expected to allocate new frequency bands before the 4^{th} mobile communication standardization, and efforts in developing a new technology are required to maximize the utilization of given bands.

Maximum frequency use efficiency is required in order to solve for a lack of frequency. Thus, a paradigm shift is needed from frequency designation and allocation, which is a national radio propagation policy, to open frequency allocation so as to flexibly use frequencies without permission.

In order to solve a lack of frequency and efficiently use previously allocated frequencies, frequency sharing technologies, such as cognitive radio (CR) and UWB, are being internationally developed.

Frequency sharing technologies enable to share frequencies without interfering with an incumbent signal service at a frequency having low use efficiency. Thus, the frequency use efficiency increases, and a progressive development of a communication system having a great possibility of accessing a communication means anytime, anywhere, and in any conditions, such as a wireless cognitive technology, is an important index of an improvement of national competitiveness in the knowledge information era, and is given a great deal of weight on an upcoming ubiquitous era.

In accordance with such trends, developed countries, such as the United States, Canada, etc., have actively supported developing frequency sharing technologies, such as a wireless cognitive technology, through a variety of national projects, and are planning to change frequency policies in order to utilize frequency sharing technologies.

The Federal Communications Committee (FCC) of the United States carried into effect the announcement of legislation regarding cognitive smart radio in December of 2003, and established a legal foundation.

The IEEE 802 has completed the IEEE 802.2 wireless regional area network (WRAN) standardization providing a wideband wireless Internet service by utilizing a locally unused frequency band based on a wireless cognitive technology in a 54-746 MHz VHF/UHF TV band.

An indispensable function of a transceiver of an IEEE 802.2 WRAN system is hindering a signal except a desired band in order to minimize interference that affects incumbent signal TV users.

Current and future communication systems require performance for using several tens of optional channels at an ultra wideband higher than several octaves.

A WRAN system is able to change a bandwidth adaptively according to a channel environment and a fixed bandwidth as well.

A band pass filter is needed to move from a TV band to an optional band channel that is unused by TV users in real time.

However, a conventional variable band pass filter was unable to be used for a variable WRAN system of a central frequency and bandwidth.

FIG. 1 is a block diagram of a conventional multi-channel band pass filter. Referring to FIG. 1, the conventional multi-channel band pass filter uses transistor switches 110 and 130 and a plurality of filter banks 120 with respect to a main channel.

An input signal is converted to a filter in accordance with an input signal channel by the transistor switch 110.

The conventional multi-channel band pass filter needs as many channels as those used in a system.

A system including the conventional multi-channel band pass filter needs an increase in channels, or needs an increase in the number and costs of components according to an increase in bands, and needs a greater installation area.

### SUMMARY OF THE INVENTION

The present invention provides a wideband variable frequency band pass filter capable of reducing the areas and expenses of filters used in a system by using a filter for varying a bandwidth and a central frequency.

The present invention also provides a wideband variable frequency band pass filter capable of varying a bandwidth in order to minimize interference of an adjacent device according to a peripheral wireless environment and a state of an interfering signal.

According to an aspect of the present invention, there is provided a wideband variable band pass filter including: a plurality of barrater diodes for changing a plurality of capacitance values based on an applied first voltage; a plurality of inductor banks comprising a plurality of switches and a plurality of inductors, and changing a plurality of inductance values based on an applied second voltage; and a filter controller for varying a central frequency and bandwidth of an input signal by combining the plurality of capacitance values of the barrater diodes and the plurality of inductance values of the plurality of inductor banks.

The barrater diodes and the plurality of inductor banks may be connected to each other in series or in parallel.

The barrater diodes and the plurality of inductor banks may be paired to each other, comprise three pairs, and have a Tee-type structure.

The barrater diodes and the plurality of inductor banks are paired to each other, may include three pairs, and have a Pi-type structure.

The filter controller may include a value of the applied first voltage, a value of the applied second voltage, information about the plurality of switches, and a look-up table (LUT) including information about the number and values of the plurality of inductors.

The central frequency and bandwidth may maintain an interference value below a predetermined value with frequency channels used by given users in a frequency band of the input signal.

The frequency band of the input signal may be an IEEE 802.22 54-746 MHz very high frequency (VHF)/ultra high frequency (UHF) band.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional multi-channel band pass filter;

FIG. 2 is a diagram of a wideband variable band pass filter capable of varying a very high frequency (VHF)/ultra high frequency (UHF) variable bandwidth and central frequency, according to an embodiment of the present invention;

FIG. 3 is a graph illustrating a simulation result of a wideband variable band pass filter according to an embodiment of the present invention;

FIG. 4 is a graph illustrating a simulation result of a wideband variable band pass filter according to another embodiment of the present invention; and

FIG. 5 is a block diagram of a wireless regional area network (WRAN) system that uses a wideband variable band pass filter according to an embodiment of the present invention.

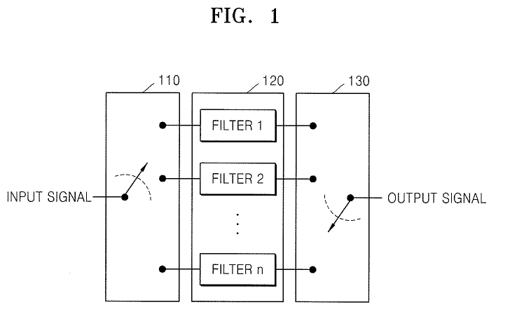

### DETAILED DESCRIPTION OF THE INVENTION

Hereinafter, the present invention will be described more fully with reference to the accompanying drawings, in which exemplary embodiments of the invention are shown. In the drawings, like reference numerals denote like elements.

A wideband variable frequency band pass filter of the present invention can be implemented as a Tee and Pi-type structure in a wideband transceiver.

A structure of a Tee-type wideband variable frequency band pass filter according to an embodiment of the present invention will now be described.

The wideband variable frequency band pass filter of the present invention implements variable capacitor components by controlling voltages applied to barrater diodes and includes inductor banks including switches used to implement various inductance values.

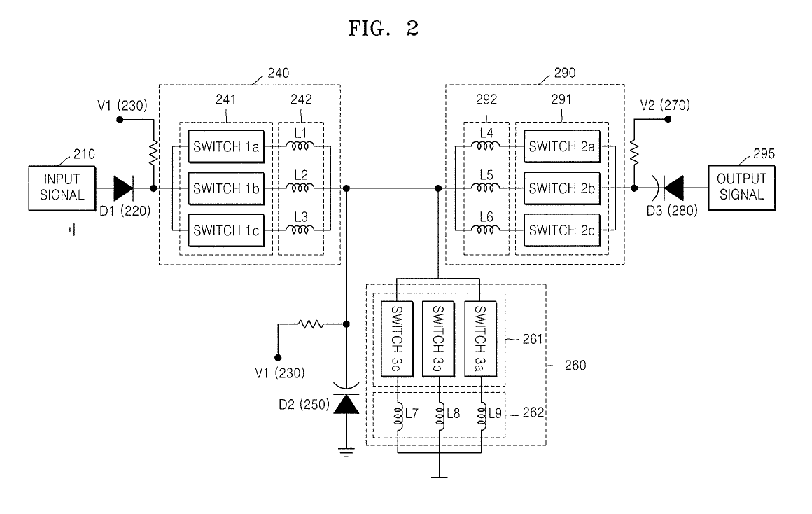

FIG. 2 is a diagram of a wideband variable band pass filter capable of varying a very high frequency (VHF)/ultra high frequency (UHF) variable bandwidth and central frequency, according to an embodiment of the present invention. Referring to FIG. 2, the wideband variable band pass filter includes a signal input unit 210, voltage controllers v1 230 and v2 270, switch and inductor bank units 240, 260, and 290, a signal output unit 295, and a filter controller (not shown).

Although a Tee-type wideband variable band pass filter is shown in FIG. 2, a Pi-type wideband variable band pass filter can have the same effect as the Tee-type wideband variable band pass filter.

The construction of the wideband variable band pass filter of the present embodiment will now be described.

The voltage controllers v1 230 and v2 270 change capacitance values by controlling voltages applied to a barrater diode.

The switch and inductor bank units 240, 260, and 290 include a plurality of switches and a plurality of inductors, and change inductance values by adjusting applied voltages.

The filter controller (not shown) varies a central frequency and bandwidth of an input signal according to a combination of the capacitance values of a barrater diode and the inductance values of the switch and inductor bank units 240, 260, and 290.

The frequency band of the input signal is a 54-746 MHz VHF/UHF band of an IEEE 802.22 wireless regional area network (WRAN) system.

The central frequency and bandwidth controlled by the filter controller (not shown) must have a minimum interference with a frequency channel used by given users in the frequency band of the input signal.

The filter controller (not shown) needs a look-up table (LUT) of voltages v1 and v2 applied to the barrater diode according to the bandwidth and central frequency and information about a LUT of switches 1a, 1b, 1c ,2a, 2b, 2c and 3a,3b,3c used to an optimum inductor value to each channel.

The number and capacity of inductors, such as L1, L2, and L3 or L4, L5, and L6, may increase from 3 to n according to a central frequency of a variable channel and a variable bandwidth in order to combine the optimum inductance values.

A variety of capacitor components can be obtained according to the control of the voltages applied to the barrater diodes, and a variety of inductor components can be obtained according to a combination of switches of the three inductor bank units 240, 260, and 290.

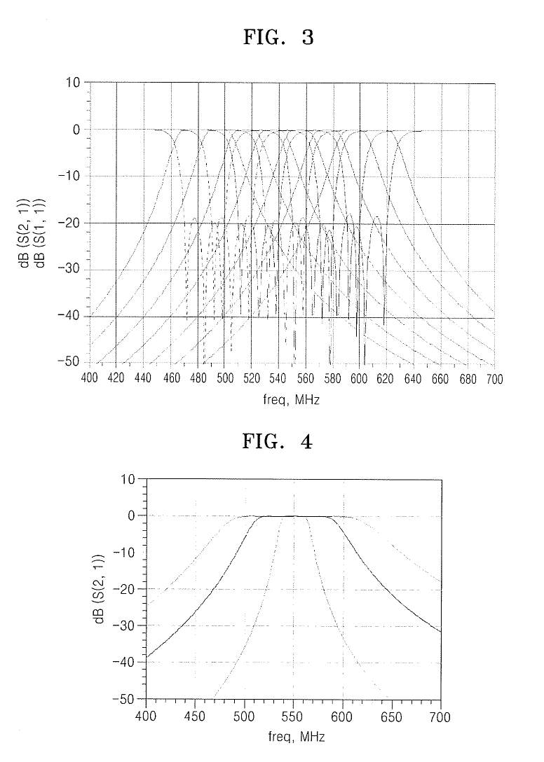

FIG. 3 is a graph illustrating a simulation result of a wideband variable band pass filter according to an embodiment of the present invention. Referring to FIG. 3, the graph shows the simulation result obtained by controlling operations of switches 1a, 1b, 1c, 2a, 2b, 2c and 3a,3b,3c used to an optimum inductor value to each central frequency with respect to voltages v1 and v2 applied to barrater diodes that have a uniform bandwidth and are used to change a central frequency.

FIG. 4 is a graph illustrating a simulation result of a wideband variable band pass filter according to another embodiment of the present invention. Referring to FIG. 4, the graph shows the simulation result obtained by controlling operations of switches 1a,1b,1c, 2a, 2b, 2c and 3a,3b,3c used to an optimum inductor value to each central frequency with respect to voltages v1 and v2 applied to the barrater diodes that have a uniform bandwidth and are used to change a central frequency.

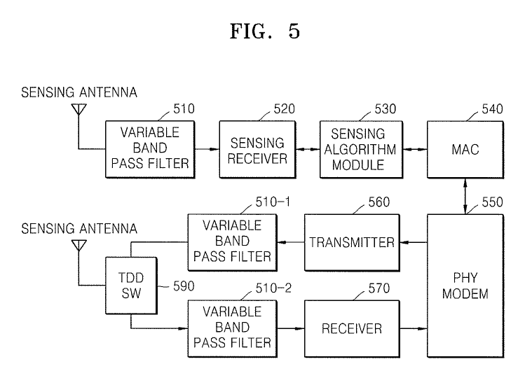

FIG. 5 is a block diagram of a WRAN system that uses a wideband variable band pass filter according to an embodiment of the present invention. Referring to FIG. 5, spectrum sensing units, which are core elements of an IEEE 802.22 WRAN system operating in a VHF/UHF wideband, continuously monitor a TV signal band between 54 MHz and 862 MHz.

In this regard, interference signals of adjacent channels provide the possibility of a reduction in performance of the spectrum sensing units.

In particular, the TV signal band varies as 6, 7, and 8 MHz according to countries, and may simultaneously receive two or more channels.

Thus, a variable band pass filter 510 that hinders a signal except a band to be sensed must be installed in a front end of a sensing receiver 520.

If a sensing algorithm module 530 determines whether the signal exceeding a band to be sensed exists, a MAC 540 determines an available channel based on the determination of the sensing algorithm module 530.

The available channel is used for an orthogonal frequency division multiplexing (OFDM) communication through time division duplex (TDD)-based WRAN transceivers 560, 570, and 590.

A bandwidth and frequency used for transceivers are also wideband. Variable band pass filters 510-1 and 510-2 are needed in a front end of the transmitter 560 and the receiver 570 in order to use an optional channel.

A wideband variable frequency band pass filter of the present invention generates a variety of inductor and capacitor values according to a combination of switches and control of voltages applied to a diode at a very high frequency (VHF)/ultra high frequency (UHF) wideband or at a band higher than the VHF/UHF wideband, thereby implementing a band pass filter capable of adjusting a bandwidth and a central frequency.

A wideband variable frequency band pass filter of the present invention can be an application of a variable low band hindrance filter and a variable high band hindrance filter and can be used for a RF transmission/reception front end and an intermediate frequency (IF) band and a base band, etc.

A wideband variable frequency band pass filter of the present invention is more efficient than a conventional variable band pass filter that needs filter banks as many as channels used in terms of price and area.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A wideband variable band pass filter comprising:
a plurality of barrater diodes for changing a plurality of capacitance values based on an applied first voltage;
a plurality of inductor banks comprising a plurality of switches and a plurality of inductors, and changing a plurality of inductance values based on an applied second voltage; and
a filter controller for varying a central frequency and bandwidth of an input signal by combining the plurality of capacitance values of the barrater diodes and the plurality of inductance values of the plurality of inductor banks.

2. The wideband variable band pass filter of claim 1, wherein the barrater diodes and the plurality of inductor banks are connected to each other in series or in parallel.

3. The wideband variable band pass filter of claim 2, wherein the barrater diodes and the plurality of inductor banks are paired to each other, comprise three pairs, and have a Tee-type structure.

4. The wideband variable band pass filter of claim 2, wherein the barrater diodes and the plurality of inductor banks are paired to each other, comprise three pairs, and have a Pi-type structure.

5. The wideband variable band pass filter of claim 1, wherein the filter controller comprises a value of the applied first voltage, a value of the applied second voltage, information about the plurality of switches, and a look-up table (LUT) including information about the number and values of the plurality of inductors.

6. The wideband variable band pass filter of claim 1, wherein the central frequency and bandwidth maintain an interference value below a predetermined value with frequency channels used by given users in a frequency band of the input signal.

7. The wideband variable band pass filter of claim 6, wherein the frequency band of the input signal is an IEEE 802.22 54-746 MHz very high frequency (VHF)/ultra high frequency (UHF) band.
